(19) United States
(12) Patent Application Publication
(10) Pub. No.: US 2007/0249128 A1
(43) Pub. Date: Oct. 25, 2007

(54) Ultraviolet (UV) Radiation Treatment Methods for Subatmospheric Chemical Vapor Deposition (SACVD) of Ozone-Tetraethoxysilane (O3-TEOS)

(76) Inventors: Junjung Kim, Fishkill, NY (US); JaeEon Park, Fishkill, NY (US); Johnny Widodo, Beacon, NY (US); Andre Schenk, Villach (AT); Alois Gutmann, Poughkeepsie, NY (US); Roland Hampp, Poughkeepsie, NY (US)

Correspondence Address: MYERS BIGEL SIBLEY & SAJOVEC, PO BOX 37428, RALEIGH, NC, 27627, US

(21) Appl. No.: 11/379,285

(22) Filed: Apr. 19, 2006

(51) Int. Cl. H01L 21/473

(52) U.S. Cl. 438/296; 438/790; 438/795; 438/424

(57) ABSTRACT

Dielectric layers are formed on a substrate by performing Subatmospheric Chemical Vapor Deposition (SACVD) of ozone-tetraethoxysilane (O₃-TEOS) to form a layer of O₃-TEOS on the substrate, and treating the layer of O₃-TEOS with ultraviolet (UV) radiation. The UV radiation treatment can increase the tensile stress in the O₃-TEOS layer by reducing the amount of water in the layer. Moreover, the UV treatment may also reduce the amount of silanol in the O₃-TEOS layer, which can also increase reliability of the device.

### FIELD OF THE INVENTION

This invention relates to integrated circuit fabrication methods, and more particularly to methods of fabricating dielectric layers for integrated circuits.

### BACKGROUND OF THE INVENTION

Integrated circuits are widely used for consumer, commercial and other applications. As is well known to those having skill in the art, dielectric (insulating) layers have many applications in integrated circuits. For example, in a Shallow Trench Isolation (STI) process and structure, STI trenches are formed in a surface of an integrated circuit substrate and filled with dielectric. Microelectronic devices, such as integrated circuit Field Effect Transistors (FETs) are formed between adjacent spaced apart STI trenches. Moreover, dielectric layers may be used on a face of an integrated circuit substrate, to electrically insulate multiple levels of conductors, such as metal, on an integrated circuit substrate from one another and/or from the substrate. The first dielectric layer between the semiconductor substrate face and a first metal layer may be referred to as a Pre-Metal Dielectric (PMD) layer, whereas the dielectric layer(s) between metal layers may be referred to as Inter-Layer Dielectric (ILD) layer(s).

It is also known that the carrier mobility in the channel region of a field effect transistor can be changed by applying stress to the channel region. In particular, tensile stress may be applied to field effect transistors, such as an n-channel field effect transistor (NFET), to increase the performance thereof. Tensile stress may be applied to a channel region of a field effect transistor by filling adjacent STI trenches with a material that produces tensile stress in the trenches, thereby imparting tensile stress to the charnel. Tensile stress also may be provided by using a PMD material that provides tensile stress.

It is known to provide a dielectric material under tensile stress by performing Subatmospheric Chemical Vapor Deposition (SACVD) of ozone-tetraethoxysilane (O₃-TEOS). The SACVD O₃-TEOS may be used to fill STI trenches and/or as a PMD layer. SACVD of TEOS is described, for example, in a publication to Shareef et al. entitled Subatmospheric chemical vapor deposition ozone/TEOS process for SiO₂ Trench filling, J. Vac. Sci. Technol. B 13(4), July/August 1995, pp. 1888-1892. SACVD of O₃-TEOS may be accomplished using a High Aspect Ratio Process (HARP) to provide good gap filling of STI trenches and/or PMD layers at high aspect ratios, such as a 7:1 aspect ratio, for highly integrated devices of about 45 nm or less, as described in an article on the Applied Materials® website, entitled Applied Producer HARP, appliedmaterials.com/products/harp.html?menuID=1_{—}3_{—}6.

Notwithstanding these developments, it may be desirable to further increase the amount of tensile stress that may be produced by SACVD O₃-TEOS.

### SUMMARY OF THE INVENTION

Dielectric layers are formed on a substrate, according to some embodiments of the present invention, by performing Subatmospheric Chemical Vapor Deposition (SACVD) of ozone-tetraethoxysilane (O₃-TEOS) to form a layer of O₃-TEOS on the substrate, and treating the layer of O₃-TEOS with ultraviolet (UV) radiation. The UV radiation treatment can increase the tensile stress in the O₃-TEOS layer by reducing the amount of water in the layer. Moreover, the UV treatment may also reduce the amount of silanol in the O₃-TEOS layer, which can also increase reliability of the device.

In some embodiments, treating the layer of O₃-TEOS with UV radiation is performed between about 400° C. and about 800° C. In other embodiments, UV treatment time between about 200 seconds and about 10 minutes is used. In yet other embodiments, the UV treatment is performed sufficiently to reduce a weight percent of water in the O₃-TEOS to below about 2%. In still other embodiments, the UV treatment is also performed sufficiently to reduce a weight percent of silanol in O₃-TEOS to below about 6%. Moreover, in some embodiments, the layer of O₃-TEOS is chemical-mechanical polished, and treating the layer of O₃-TEOS with UV radiation may be performed before and/or after the chemical-mechanical polishing.

Integrated circuits may be fabricated according to some embodiments of the present invention, by forming in a face of an integrated circuit substrate, spaced apart Shallow Trench Isolation (STI) trenches. SACVD of O₃-TEOS is then performed to form a layer of O₃-TEOS in the STI trenches. The O₃-TEOS layer in the STI trenches is treated with UV radiation. In other embodiments, SACVD of O₃-TEOS is again performed on the face of the integrated circuit substrate to form a layer of O₃-TEOS on the face of the integrated circuit substrate. The layer of O₃-TEOS on the face of the integrated circuit is treated with UV radiation. Parameters of the UV treatments may be as described above.

In some embodiments, spaced apart source and drain regions and a channel region therebetween, are formed in the integrated circuit substrate between the spaced apart STI trenches, and the UV treatment of the layer of O₃-TEOS in the STI is performed sufficiently to increase stress in the channel region that is imparted by the layer of O₃-TEOS in STI trenches. Moreover, in other embodiments, the layer of )₃-TEOS on the face of the integrated circuit substrate is UV treated sufficiently to increase stress in the channel region that is imparted by the layer of O₃-TEOS on the face of the substrate. In some embodiments, the UV treating of the O₃-TEOS in the STI trenches and on the face of the integrated circuit substrate is performed sufficiently to increase stress in the channel region that is imparted by the layer of O₃-TEOS in the STI trenches and by the layer of O₃-TEOS on the face of the substrate by at least about 30 megapascal (MPa). Parameters of the UV treatments may be as described above.

In other embodiments of the present invention, tensile stress in a channel region of an integrated circuit field effect transistor that is imparted by a first SACVD O₃-TEOS layer in a trench isolation region adjacent the field effect transistor and by a second SACVD O₃-TEOS layer on the field effect transistor is increased by treating the first and/or second layers of O₃-TEOS with UV radiation. In some embodiments, both the first and second layers of O₃-TEOS are treated with UV radiation. Parameters of the UV treatments may be as described above.

### BRIEF DESCRIPTION OF THE DRAWINGS

FIG. 1 is a cross-sectional view of an integrated circuit field effect transistor that includes subatmospheric chemical vapor deposited (SACVD) layers of ozone-tetraethoxysilane (O₃-TEOS) to provide a Shallow Trench Isolation (STI) layer and a Pre-Metal Dielectric (PMD) layer.

FIG. 2 graphically illustrates tensile stress imparted into the channel of a field effect transistor device by the O₃-TEOS STI and PMD layers of FIG. 1.

FIGS. 3-5 are cross-sectional views illustrating ultraviolet (UV) treatment of an STI O₃-TEOS layer, according to some embodiments of the present invention.

FIGS. 6 and 7 are cross-sectional views illustrating UV treatment of a PMD O₃-TEOS layer, according to some embodiments of the invention.

FIG. 8 graphically illustrates the effect of UV treatment on stress in a channel of devices of FIG. 6, according to some embodiments of the present invention.

FIG. 9 graphically illustrates absorbance in a 7000 Å layer of SACVD O₃-TEOS before and after UV treatment, according to some embodiments of the present invention.

### DETAILED DESCRIPTION

The invention will be described more fully hereinafter with reference to the accompanying drawings, in which example embodiments of the invention are shown. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. In the drawings, the size and relative sizes of layers and regions may be exaggerated for clarity unless express so defined herein. Moreover, each embodiment described and illustrated herein includes its complementary conductivity type embodiment as well. Like numbers refer to like elements throughout.

It will be understood that when an element or layer is referred to as being “on”, “connected to” and/or “coupled to” another element or layer, it can be directly on, connected or coupled to the other element or layer or intervening elements or layers may be present. In contrast, when an element is referred to as being “directly on,” “directly connected to” and/or “directly coupled to” another element or layer, there are no intervening elements or layers present. As used herein, the term “and/or” may include any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms may be used to distinguish one element, component, region, layer and/or section from another region, layer and/or section. For example, a first element, component, region, layer and/or section discussed below could be termed a second element, component, region, layer and/or section without departing from the teachings of the present invention.

Spatially relative terms, such as “beneath”, “below”, “lower”, “above”, “upper” and the like, may be used herein for ease of description to describe an element and/or a features relationship to another element(s) and/or feature(s) as illustrated in the figures. It will be understood that the spatially relative terms are intended to encompass different orientations of the device in use or operation in addition to the orientation depicted in the figures. For example, if the device in the figures is turned over, elements described as “below” and/or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular terms “a”, “an” and “the” are intended to include the plural forms as well, unless the context clearly indicates otherwise. It will be further understood that the terms “comprises,” “comprising,” “includes” and/or “including” when used in this specification, specify the presence of stated features, integers, steps, operations, elements, and/or components, but do not preclude the presence or addition of one or more other features, integers, steps, operations, elements, components, and/or groups thereof.

Example embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, may be expected. Thus, the disclosed example embodiments of the invention should not be construed as limited to the particular shapes of regions illustrated herein unless expressly so defined herein, but are to include deviations in shapes that result, for example, from manufacturing. Thus. the regions illustrated in the figures are schematic in nature and their shapes are not intended to illustrate the actual shape of a region of a device and are not intended to limit the scope of the invention, unless expressly so defined herein.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

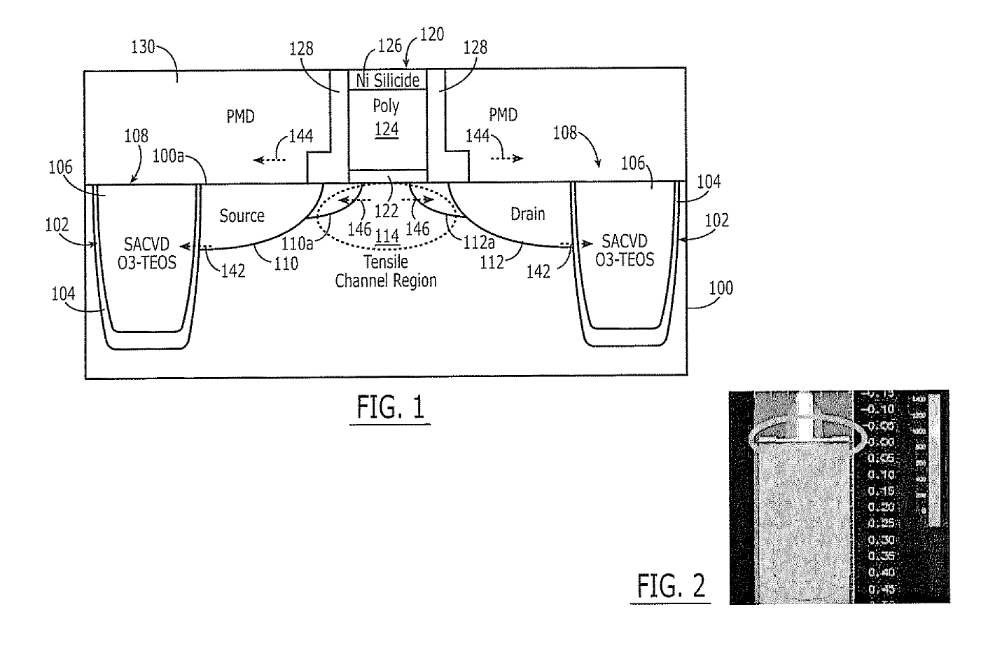

FIG. 1 is a cross-sectional view of an integrated circuit field effect transistor that includes Subatmospheric Chemical Vapor Deposited (SACVD) layers of ozone-tetraethoxysilane (O₃-TEOS), to provide a Shallow Trench Isolation (STI) layer and a Pre-Metal Dielectric (PMD) layer. Referring to FIG. 1, an integrated circuit includes an integrated circuit substrate 100, such as a silicon semiconductor substrate. Spaced apart trenches 102 are provided at a face 100a of the substrate 100. The trenches 102 may be filled by an optional trench liner 104 and a layer of SACVD O₃-TEOS 106. The SACVD O₃-TEOS 106 and the optional trench liner 104 in the trenches 102 define STI regions 108.

Still referring to FIG. 1, a Field Effect Transistor (FET) is provided between adjacent STI regions 108. More specifically, spaced apart source and drain regions 110 and 112 are provided between the adjacent STI regions 108, to define a channel region 114 therebetween, at the face 100a of the substrate 100. A gate structure 120, which may include a gate dielectric 122, a polysilicon gate 124, a gate silicide layer 126 and gate spacers 128, is provided on the channel region 114. Source and drain extension regions 110a, 112a, respectively, also may be provided. An SACVD O₃-TEOS insulating layer 130 is provided on the face 100a, including on the source 110 and drain 112 regions. The insulating layer 130 may be referred to as a Pre-Metal Dielectric (PMD).

It will be understood by those having skill in the art that the STI regions 108, the source/drain regions 110/112, the source/drain extensions 110a/112a and the gate structure 120 may be fabricated in any arbitrary order or sequence relative to one another, which may vary according to different process recipes. Moreover, all of the regions described above need not be included. For example, a trench liner 104, source/drain extensions 110a/112a, various layers of the gate structure 120 and/or gate spacers 128 may be omitted according to various FET designs.

As also illustrated in FIG. 1, the SACVD O₃-TEOS layer 106 in the STI regions 108 may be under tensile stress, as shown by arrows 142, and the PMD layer 130 may be under tensile stress, as shown by arrows 144, to collectively impart tensile stress in the channel region 114, as shown by arrows 146. More specifically, as shown by the circled region of FIG. 2, in a 45 nm n-channel FET (NFET), over 1 gigapascal (GPa) of tensile stress may be imparted in the channel by the STI and PMD layers. This tensile stress may create a 2-10% improvement in the saturation current of the device.

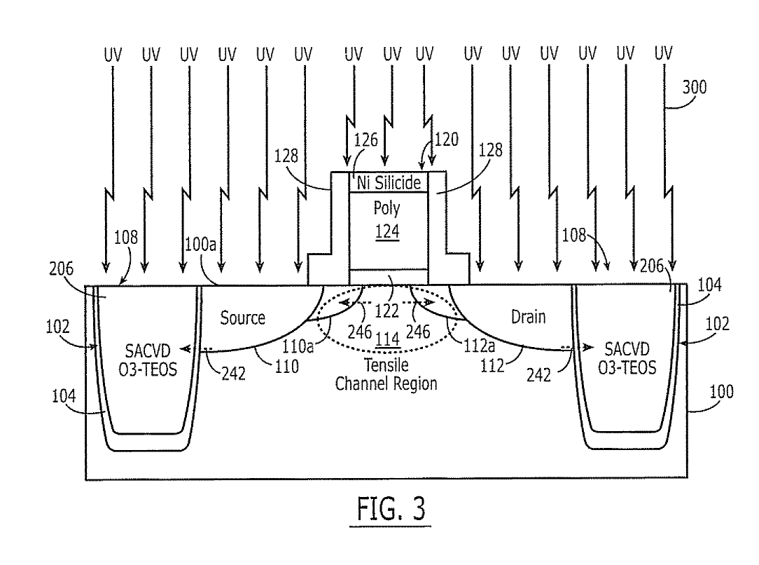

FIG. 3 is a cross-sectional view of methods of treating an STI layer of O₃-TEOS, according to some embodiments of the present invention. As shown, an SACVD O₃-TEOS layer 206 in the STI trench 102 is treated with ultraviolet (UV) radiation 300, to increase the tensile stress 242 in the UV treated SACVD O₃-TEOS layer 206. The tensile stress 246 that is imparted to the channel 114 may thereby be increased.

In some embodiments, UV treating the layer of O₃-TEOS 206 in the STI region 108 may be performed at between about 400° C. and about 800° C. In other embodiments, treatment with the UV radiation 300 may be performed for between about 200 seconds and about 10 minutes. As will be described in more detail below, it has been found, according to some embodiments of the present invention, that treating the layer of O₃-TEOS 206 in the STI regions 108 with UV radiation 300 may be performed sufficiently to reduce a weight percent of water in the O₃-TEOS to below about 2%. In other embodiments, the UV treatment may also be performed sufficiently to reduce a weight percent of silanol in the O₃-TEOS to below about 6%.

In some embodiments of the present invention, the UV treatment 300 may take place in a Tokyo Electron UV tool, using a UV wavelength of about 172 nm and a power of about 50 mW/cm². Other specifications for the UV tool are shown in the following Table:

TABLE

| Item | | | Spec |
|---|---|---|---|
| Radical | UV Lamp | Lamp Power | Max 50 mW/cm² |
| | (172 nm) | Lamp Power Range | ˜70%, ˜20% |
| | | Life | ˜1000 h |
| | Remote Plasma | Output | 13.56 MHz |
| Chamber | Stage | Rotation Speed | Max 60 rpm |
| | Wall Heater | Wall Temperature | Room Temperature |
| | Shape | Capacity | 20˜30 L |
| | Vacuum | Pressure Control | 1e−2˜20 Torr |
| | Characteristic | Range | <1e−6 Torr/sec |
| | | Leak Rate | |
| Heater | Temperature | Uniformity | ±1% C. @700° C. |
| | | Process | 300˜700° C. |
| | | Temperature | |
| Gas | Supply | Gas | Standard: |
| | | Piping Inside | 02, N2, Ar |
| | | Treatment | SUS316 Electrical |
| | | | Polish |
| | Pump | Model | Wide range TMP |
| | | Pumping Speed | 800 L/sec |

However, it will be understood by those having skill in the art that other UV tools with other specifications also may be used according to embodiments of the present invention

It will be understood by those having skill in the art that the UV treatment 300 of FIG. 3 may be performed one or more times during the fabrication process of the device of FIG. 3, after SACVD of the O₃-TEOS 206 in the STI region 108. Thus, the UV treatment 300 may take place before forming the FET, at one or more intermediate times during the FET device fabrication process and/or after the FET is fabricated. In some embodiments, the UV treatment 300 of FIG. 3 takes place before the STI regions 108 are covered, for example by a PMD layer and/or another layer. Moreover, in some embodiments of the invention, the UV treatment 300 takes place in a UV treatment chamber that is different from the chamber at which SACVD of the O₃-TEOS takes place. However, in other embodiments, in situ UV treatment may be performed. In situ UV treatment may take place concurrent with and/or after SACVD of the O₃-TEOS layer.

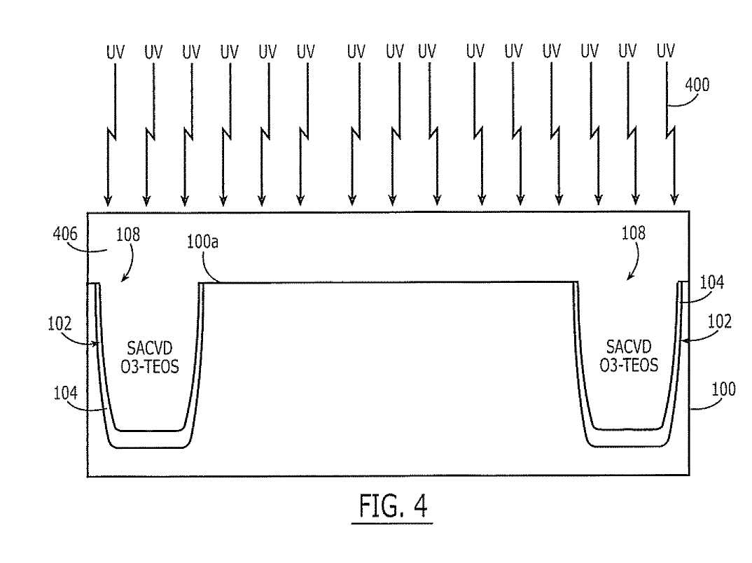

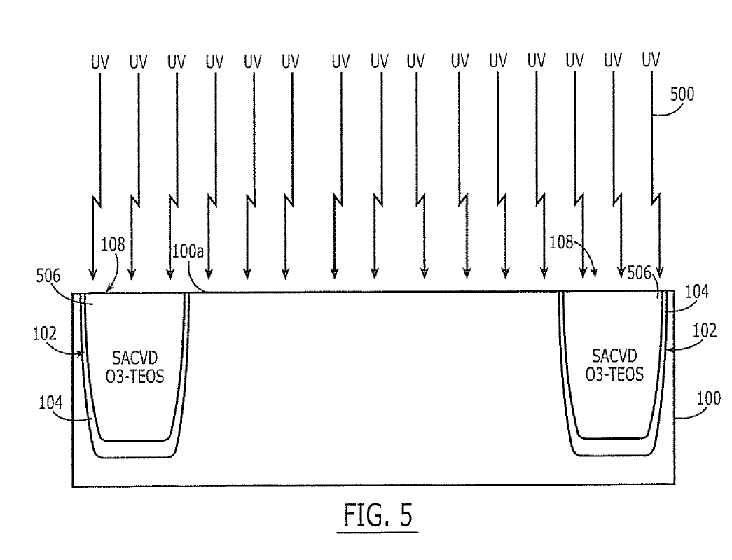

In some embodiments of the invention, in forming the O₃-TEOS 206 in the STI region 108, a blanket layer of O₃-TEOS is deposited by SACVD, and then the layer of SACVD O₃-TEOS is Chemical-Mechanical Polished (CMP). In these embodiments, the layer of O₃-TEOS may be treated with UV radiation before and/or after the CMP. For example, FIG. 4 illustrates SACVD of O₃-TEOS 406 in the STI regions 108 and on the face 100a of the substrate 100, followed by UV treatment 400. FIG. 5 illustrates UV treatment 500 of the SACVD O₃-TEOS layer 506 in the STI region 108, after CMP, but before fabrication of the gate structure 120. Embodiments of FIGS. 3, 4 and 5 may be used individually, in subcombination or in combination. Moreover, parameters for the UV treatment may be the same, or may be different, depending on when the UV treatment is performed.

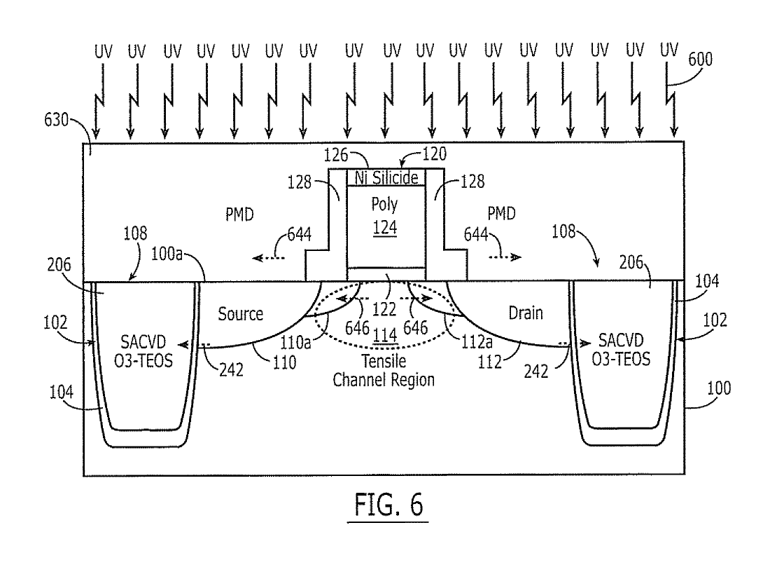

FIG. 6 illustrates the fabrication of a PMD layer 630 using SACVD of O₃-TEOS, followed by treatment with UV radiation 600, according to some embodiments of the invention. The UV treated PMD layer 630 provides an increased tensile stress 644 therein, which can increase the tensile stress 646 that is imparted to the channel region 114. In some embodiments, parameters for the UV treatment 600 may be the same as the parameters for the UV treatment 300 described in FIG. 3. In other embodiments, different parameters may be used based on, for example, the different thickness and/or composition of the PMD layer relative to the STI layer 106.

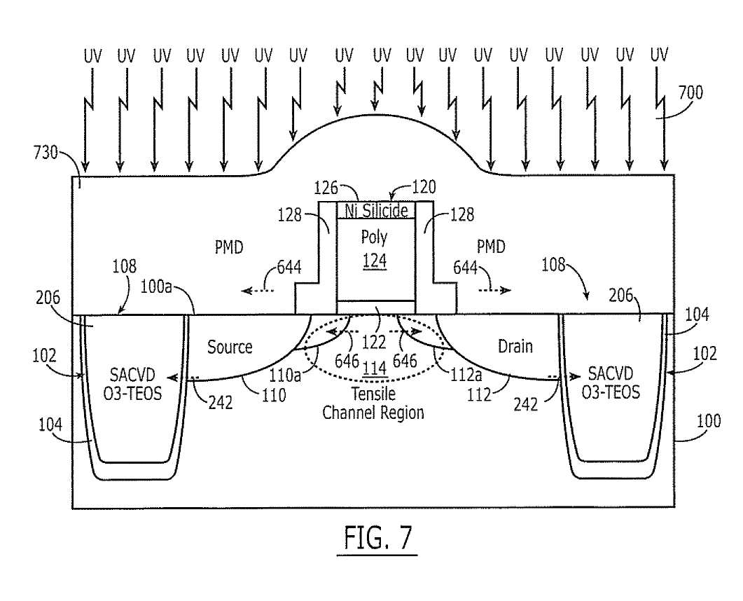

As was the case with the STI layer 206, the PMD layer 430 may also be formed by CMP a layer of O₃-TEOS on the face of the integrated substrate. In these embodiments, treating the layer of O₃-TEOS on the face of the integrated circuit substrate with UV radiation may be performed before and/or after the CMP. For example, as shown in FIG. 7, an SACVD O₃-TEOS PMD layer 730 is formed on the face 100a of the integrated circuit substrate 100, including on the gate structure 120. UV treatment 700 may be performed on the PMD layer 730. Then, as was already shown in FIG. 6, CMP of the PMD layer 730 may take place to recess the PMD layer 630 compared to FIG. 7. In some embodiments, the PMD layer 630 may be recessed flush with the gate structure 120. UV treatments 600 and/or 700 may be performed using the parameters that were described above. In other embodiments, different parameters may be used based on, for example, the thickness of the PMD layer.

It will be understood by those having skill in the art that although FIGS. 3-7 illustrate UV treatment being applied to the SACVD O₃-TEOS STI layer and the SACVD O₃-TEOS PMD layer, other embodiments of the invention may treat only the STI layer or the PMD layer It will also be understood by those having skill in the art that although separate UV treatments are shown for the PMD layer and the STI layer, a single UV treatment may penetrate both layers if the PMD layer is sufficiently thin.

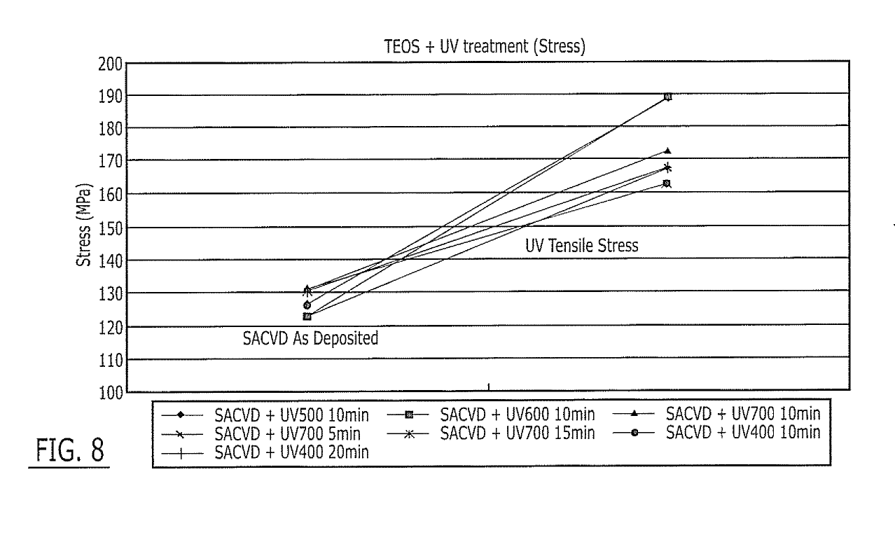

FIG. 8 Graphically illustrates the effect of UV treatment on stress in a channel 114 of devices of FIG. 6, according to some embodiments of the present invention. In particular, FIG. 8 graphically illustrates stress in the channel 114 of a 45 nm NFET for which an O₃-TEOS layer 206 was deposited in the STI region 108 using SACVD, and for which a PMD layer 630 also was deposited using SACVD. Seven wafer samples are illustrated. On the left side of the graph, the “as deposited” stress in the channel is measured, and on the right side of the graph the stress after two UV treatments is measured. UV treatments at 400° C., 500° C., 600° C. and 700° C., as well as at 5 minutes, 10 minutes, 15 minutes and 20 minutes, are shown. As shown in FIG. 8, UV treatments according to some embodiments of the present invention can increase stress in the channel region 114 from the O₃-TEOS 206 in the STI regions 108 and from the PMD layer of O₃-TEOS 630 on the spaced apart source and drain regions 110, 112 by at least about 30 MPa (i.e., from about 130 MPa or less to at least about 160 MPa). As also shown in FIG. 8, an increase of about 65 MPa may be obtained, according to some embodiments of the invention, for UV treatments at 600° C. for 10 minutes.

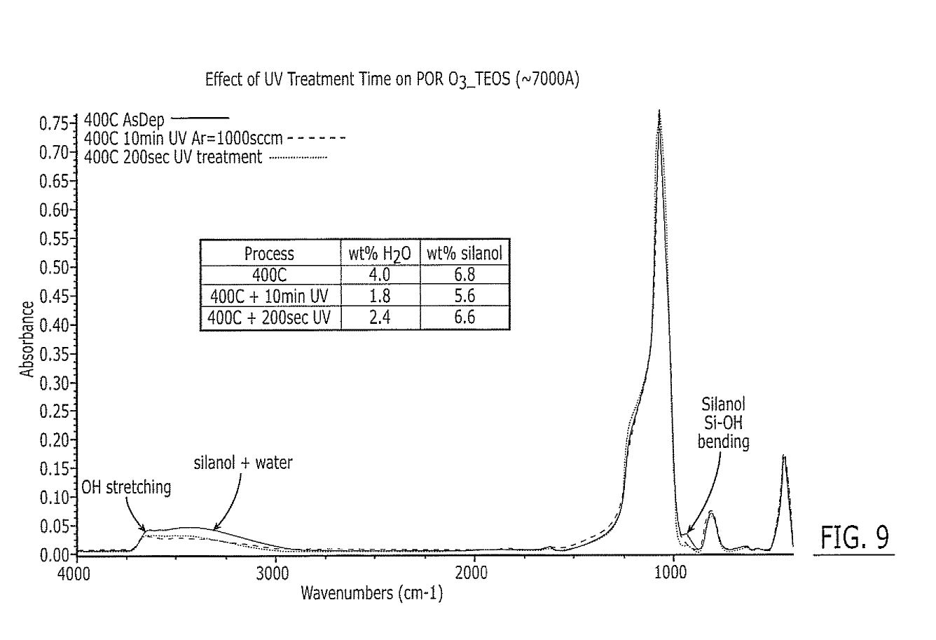

FIG. 9 graphically illustrates changes in an O₃-TEOS film before and after UV treatment according to some embodiments of the present invention. As shown in FIG. 9, an as deposited layer of SACVD TEOS of about 7,000 Å thick that was heat treated at about 400° C. includes about 4% by weight water and about 6.8% by weight silanol. After about 10 minutes of UV treatment at 400° C., the weight percent water decreases to about 1.8%, and the weight percent of silanol decreases to about 5.6%. In contrast, after about 200 seconds of UV treatment at 400° C., the weight percent water decreases to about 2.4%, and the weight percent of silanol only decreases marginally to about 6.6%. Referring to the absorbance graphs, OH stretching is shown to be reduced, the amount of silanol+water is decreased, and silanol Si—OH bending is decreased.

Accordingly, FIG. 9 illustrates that the UV treatment may be performed sufficiently to reduce a weight percent of water in the O₃-TEOS to below about 2%, according to some embodiments of the present invention. Moreover, FIG. 9 illustrates that, according to some embodiments of the present invention, UV treatment may be performed to reduce the weight percent of silanol in the O₃-TEOS to below about 6%. Moreover, FIG. 9 illustrates that UV treatment may take place at between about 200 seconds and about 10 minutes although, in some embodiments, 10 minutes may be more effective in reducing the weight percent water and the weight percent silanol. By reducing the amount of water in the O₃-TEOS, a larger amount of tensile stress may be provided. Moreover, by removing silanol from the film, the film may become more moisture resistant and reliability may increase.

Without wishing to be bound by any theory of operation, it appears that UV treatment(s) according to some embodiments of the present invention can reduce moisture present in an SACVD O₃-TEOS film, and can reduce or prevent additional moisture from being incorporated into SACVD O₃-TEOS film, which can increase the tensile strength and/or increase the reliability of the film. In particular, an SACVD O₃-TEOS film may include (Si—O)ₓ-Hy therein. The combination of UV radiation and heat can provide outgassing of H₂O and Si—OH. This can cause further shrinkage in the SACVD O₃-TEOS film, which can increase tensile stress.

It is known to use High Density Plasma (HDP) CVD technology to deposit O₃-TEOS. HDPCVD may be a very slow and expensive process, but may be practically free of moisture. SACVD can be faster and cheaper, but can have a significant amount of moisture incorporated in the film, due to incomplete reaction of the chemical precursors. Some embodiments of the present invention can reduce the moisture in the film to an insignificant level. Moreover, the UV treatment can cause the remaining moisture in the film to react to form stable products, so the film will no longer incorporate significant moisture.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A method of forming a dielectric layer on a substrate comprising:
performing subatmospheric chemical vapor deposition (SACVD) of ozone-tetraethoxysilane (O₃-TEOS) to form a layer of O₃-TEOS on the semiconductor substrate; and
treating the layer of O₃-TEOS with ultraviolet (UV) radiation.

2. A method according to claim 1 wherein treating the layer of O₃-TEOS with UV radiation is performed at between about 400° C. and about 800° C.

3. A method according to claim 1 wherein treating the layer of O₃-TLOS with UV radiation is performed sufficiently to reduce a weight percent of water in the O₃-TEOS to below about 2 weight percent.

4. A method according to claim 2 wherein treating the layer of O₃-TEOS with UV radiation is performed for between about 200 seconds and about 10 minutes.

5. A method according to claim 3 wherein treating the layer of O₃-TEOS with UV radiation is also performed sufficiently to reduce a weight percent of silanol in the O₃-TEOS to below about 6 weight percent.

6. A method according to claim 1 further comprising chemical-mechanical polishing the layer of O,-TEOS, and wherein treating the layer of O₃-TEOS with UV radiation is performed before and/or after the chemical-mechanical polishing.

7. A method of forming an integrated circuit comprising:
forming in a face of an integrated circuit substrate, spaced-apart Shallow Trench Isolation (STI) trenches;
performing subatmospheric chemical vapor deposition (SACVD) of ozone-tetraethoxysilane (O₃-TEOS) to form a layer of O₃-TEOS in the STI trenches; and
treating the layer of O₃-TEOS in the STI trenches with ultraviolet (UV) radiation.

8. A method according to claim 7 wherein treating is followed by:
again performing SACVD of O₃-TEOS on the face of the integrated circuit substrate to form a layer of O₃-TEOS on the face of the integrated circuit substrate; and
treating the layer of O₃-TEOS on the face of the integrated circuit substrate with ultraviolet (UV) radiation.

9. A method according to claim 7 further comprising:
forming spaced apart source and drain regions and a channel therebetween, in the integrated circuit substrate between the spaced apart STI trenches; and
wherein treating the layer of O₃-TEOS in the STI trenches with UV radiation is performed sufficiently to increase stress in the channel region that is imparted by the layer of O₃-TEOS in the STI trenches.

10. A method according to claim 8:
wherein again performing SACVD of O₃-TEOS on the face of the integrated circuit substrate to form a layer of O₃-TEOS on the face of the integrated circuit substrate is preceded by forming spaced apart source and drain regions and a channel therebetween, in the integrated circuit substrate between the spaced apart STI trenches;
wherein again performing SACVD of O₃-TEOS on the face of the integrated circuit substrate to form a layer of O₃-TEOS on the face of the integrated circuit substrate comprises again performing SACVD of O₃-TEOS on the face of the integrated circuit substrate to form a layer of O₃-TEOS on the spaced apart source and drain regions; and
wherein treating the layer of O₃-TEOS in the STI trenches and treating the layer of O₃-TEOS on the face of the integrated circuit substrate with UV radiation are performed sufficiently to increase stress in the channel region that is imparted by the layer of O₃-TEOS in the STI trenches and by the layer of O₃-TEOS on the spaced apart source and drain regions by at least about 30 MPa.

11. A method according to claim 7 wherein treating the layer of O₃-TEOS in the STI trenches with UV radiation is performed at between about 400° C. and about 800° C.

12. A method according to claim 7 wherein treating the layer of O₃-TEOS in the STI trenches with UV radiation is performed sufficiently to reduce a weight percent of water in the O₃-TEOS to below about 2 weight percent.

13. A method according to claim 11 wherein treating the layer of O₃-TEOS in the STI trenches with UV radiation is performed for between about 200 seconds and about 10 minutes.

14. A method according to claim 12 wherein treating the layer of O₃-TEOS in the STI trenches with UV radiation is performed sufficiently to reduce a weight percent of silanol in the O₃-TEOS to below about 6 weight percent.

15. A method according to claim 7 further comprising chemical-mechanical polishing the layer of O₃-TEOS, and wherein treating the layer of O₃-TEOS with UV radiation is performed before and/or after the chemical-mechanical polishing.

16. A method according to claim 8 further comprising chemical-mechanical polishing the layer of O₃-TEOS on the face of the integrated circuit substrate. and wherein treating the layer of O₃-TEOS on the face of the integrated circuit substrate with UV radiation is performed before and/or after the chemical-mechanical polishing.

17. A method of increasing tensile stress in a channel region of an integrated circuit field effect transistor that is imparted by a first subatmospheric chemical vapor deposited (SACVD) ozone-tetraethoxysilane (O₃-TEOS) layer in a trench isolation region adjacent the field effect transistor and by a second SACVD O₃-TEOS layer on the field effect transistor, the method comprising:
treating the first and/or second layers of O₃-TEOS with ultraviolet (UV) radiation.

18. A method according to claim 17 wherein treating the first and/or second layers of O₃-TEOS with UV radiation comprises treating both the first and second layers of O₃-TEOS with UV radiation.

19. A method according to claim 17 wherein treating the first and/or second layers of O₃-TEOS with UV radiation is performed at between about 400° C. and about 800° C.

20. A method according to claim 17 wherein treating the first and/or second layers of O₃-TEOS with UV radiation is performed sufficiently to reduce a weight percent of water in the O₃-TEOS to below about 2 weight percent.

21. A method according to claim 19 wherein treating the first and/or second layers of O₃-TEOS with UV radiation is performed for between about 200 seconds and about 10 minutes.

22. A method according to claim 20 wherein treating the first and/or second layers of O₃-TEOS with UV radiation is performed sufficiently to reduce a weight percent of silanol in the O₃-TEOS to below about 6 weight percent.

23. A method according to claim 17 wherein treating the first and/or second layers of O₃-TEOS with UV radiation is performed sufficiently to increase stress in the channel region by at least about 30 MPa.
